(19) United States
(12) Patent Application Publication
(10) Pub. No.: US 2024/0213303 A1
(43) Pub. Date: Jun. 27, 2024

(54) CAPACITOR, SEMICONDUCTOR DEVICE INCLUDING THE SAME AND ELECTRONIC APPARATUS

(71) Applicant: Samsung Electronics Co., Ltd., Suwon-si (KR)

(72) Inventors: Boeun PARK, Suwon-si (KR); Haeryong KIM, Suwon-si (KR); Euncheol DO, Suwon-si (KR); Cheheung KIM, Suwon-si (KR); Jooho LEE, Suwon-si (KR)

(73) Assignee: Samsung Electronics Co., Ltd., Suwon-si (KR)

(21) Appl. No.: 18/347,938

(22) Filed: Jul. 6, 2023

(30) Foreign Application Priority Data
Dec. 23, 2022 (KR) 10-2022-0183215

(51) Int. Cl. H01G 4/08; H01G 4/33; H01L 29/51; H01L 29/94; H10B 12/00; H01G 4/008

(52) U.S. Cl. CPC H01L 28/56; H01G 4/085; H01G 4/33; H01L 29/511; H01L 29/517; H01L 29/518; H01L 29/94; H10B 12/31; H01G 4/008

(57) ABSTRACT

Provided is a capacitor, a semiconductor device including the same, and an electronic apparatus including the semiconductor device, wherein the capacitor includes a first electrode including a first metal ion, a second electrode arranged spaced apart from the first electrode, a dielectric layer provided between the first electrode and the second electrode, and an interfacial layer provided between the first electrode and the dielectric layer and including a compound represented by MₓO_{y}N_{z}, in which a diffusion energy barrier value of M is equal to or greater than a diffusion energy barrier value of the first metal ion.

### CROSS-REFERENCE TO RELATED APPLICATION

This application is based on and claims priority under 35 U.S.C. § 119 to Korean Patent Application No. 10-2022-0183215, filed on Dec. 23, 2022, in the Korean Intellectual Property Office, the disclosure of which is incorporated by reference herein in its entirety.

### BACKGROUND

### 1. Field

The present disclosure relates to a capacitor, a semiconductor device including the same, and an electronic apparatus including the semiconductor device.

### 2. Description of the Related Art

As electronic apparatuses are being down-scaled, the space available to be occupied by electronic components, such as capacitors, within the electronic apparatuses is also decreasing. Accordingly, as the size of the electronic components, such as a capacitor, and/or semiconductor devices including the electronic components is decreased, a reduction in the thickness of a dielectric layer of the capacitor is simultaneously required. However, in this case, high heat conditions may be required to form the dielectric layer, and deterioration of the dielectric layer may be caused during a process of preparing the capacitor.

### SUMMARY

At least one embodiment provides a capacitor with high capacitance and a semiconductor device including the same.

Additional aspects will be set forth in part in the description which follows and, in part, will be apparent from the description, or may be learned by practice of the presented embodiments of the disclosure.

According to an aspect, provided is a capacitor, including: a first electrode including a first metal ion; a second electrode spaced apart from the first electrode; a dielectric layer between the first electrode and the second electrode, the dielectric layer comprising a dielectric material with a perovskite crystal structure; and an interfacial layer between the first electrode and the dielectric layer, the interfacial layer including a compound represented by MₓO_{y}N_{z}, wherein a diffusion energy barrier value of M is greater than or equal to a diffusion energy barrier value of the first metal ion.

According to an aspect, provided is a semiconductor device, including: a field-effect transistor; and a capacitor electrically connected to the field-effect transistor, wherein the capacitor includes a first electrode including a first metal ion; a second electrode spaced apart from the first electrode; a dielectric layer between the first electrode and the second electrode; and an interfacial layer between the first electrode and the dielectric layer, the interfacial layer including a compound represented by MₓO_{y}N_{z}, wherein a diffusion energy barrier value of M is greater than or equal to a diffusion energy barrier value of the first metal ion.

According to still another aspect, provided is an electronic apparatus including the semiconductor device according to each embodiment.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a capacitor according to at least one embodiment;

FIG. 2 illustrates a semiconductor device according to at least one embodiment;

FIG. 3 illustrates a semiconductor device according to at least one embodiment;

FIG. 4 is a cross-sectional view taken along a line A-A′ in FIG. 3;

FIG. 5 illustrates a semiconductor device according to still at least one embodiment;

FIG. 6 is a conceptual diagram schematically illustrating an element architecture applicable to an electronic apparatus according to at least one embodiment; and

FIG. 7 is a conceptual diagram schematically illustrating an element architecture applicable to an electronic apparatus according to at least one embodiment.

### DETAILED DESCRIPTION

Reference will now be made in detail to some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, example embodiments will be described in detail with reference to the accompanying drawings. In the following drawings, a size of each component in the drawings may be exaggerated for clarity and convenience of description. Meanwhile, the embodiments described below are merely example, and various modifications are possible from these embodiments.

Hereinafter, the expressions “above” or “on” not only indicates the state that a thing is in contact with something else and is directly above, below, left, or right, but also the state when a thing has no contact with something else and is above, below, left, or right unless expressly indicated otherwise. For example, it will be understood that such spatially relative terms are intended to encompass different orientations of the device in use or operation in addition to the orientation depicted in the figures, and that the device may be otherwise oriented (rotated 90 degrees or at other orientations) and the spatially relative terms used herein interpreted accordingly. The singular of any term includes the plural unless the context otherwise requires. In addition, when a part “includes” a component, unless otherwise specified, it does not exclude other components but may further include other components. When the terms “about” or “substantially” are used in this specification in connection with a numerical value, it is intended that the associated numerical value includes a manufacturing tolerance (e.g., +10%) around the stated numerical value. Further, regardless of whether numerical values are modified as “about” or “substantially,” it will be understood that these values should be construed as including a manufacturing or operational tolerance (e.g., +10%) around the stated numerical values.

The term “above-mentioned” and similar denoting terms may refer to both singular and plural. Unless an order of steps constituting a method is explicitly stated, is contrary to a description of the steps, these steps may be performed in any suitable order, and are not necessarily limited to the order described.

It will be understood that, although the terms “first”, “second”, “third”, etc., may be used herein to describe various elements, these terms are only used to distinguish one element from another element, and the order, type, etc. of the elements are not limited. When there is an explicit description of the order of operations of the method or there is no description contrary thereto, these operations may be performed in an appropriate order and the order is not necessarily limited to the described order.

The functional elements described herein using terms such as “ . . . unit” described in the specification mean a unit that processes at least one function or operation, which may be implemented as processing circuitry such as hardware or software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components. For example, the processing circuitry may include electrical components such as logic gates including at least one of AND gates, OR gates, NAND gates, NOT gates, etc., and/or electronic circuits including said components. Connections or connecting members of lines between components shown in the drawings are illustrative of functional connections and/or physical or circuit connections, which may be replaced or additionally provided by a variety of functional connections, physical connections, or circuit connections.

Use of all examples or example terms is simply for explaining technical ideas in detail, and the scope is not limited to these examples or example terms, unless limited by the claims.

According to an aspect, a capacitor with high capacitance may be provided.

A capacitor according to at least one embodiment includes: a first electrode including a first metal ion; a second electrode spaced apart from the first electrode; a dielectric layer between the first electrode and the second electrode; and an interfacial layer between the first electrode and the dielectric layer, and including a compound represented by MₓO_{y}N_{z}. In addition, a diffusion energy barrier value of M is greater than or equal to a diffusion energy barrier value of the first metal ion.

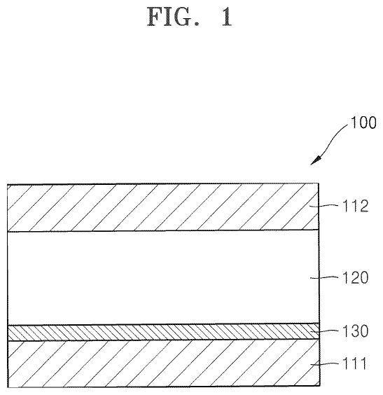

FIG. 1 is a cross-sectional view of a capacitor 100 according to at least one embodiment. The capacitor 100 shown in FIG. 1 may be referred to as a unit capacitor.

Referring to FIG. 1, the capacitor 100 includes first and second electrodes 111 and 112 which are spaced apart from each other, and a dielectric layer 120 provided between the first and second electrodes 111 and 112. In addition, a leakage current reducing layer 130 is provided between the first electrode 111 and the dielectric layer 120. The leakage current reducing layer 130 may also be referred to as an interfacial layer 130.

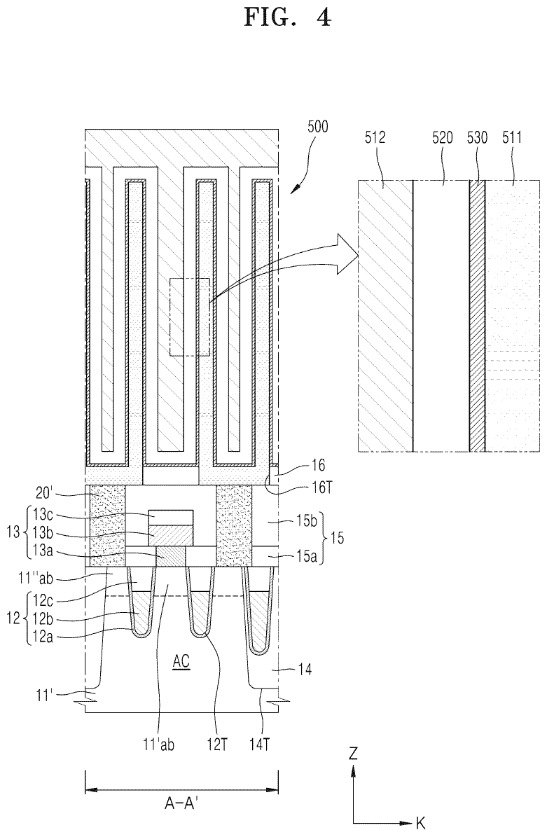

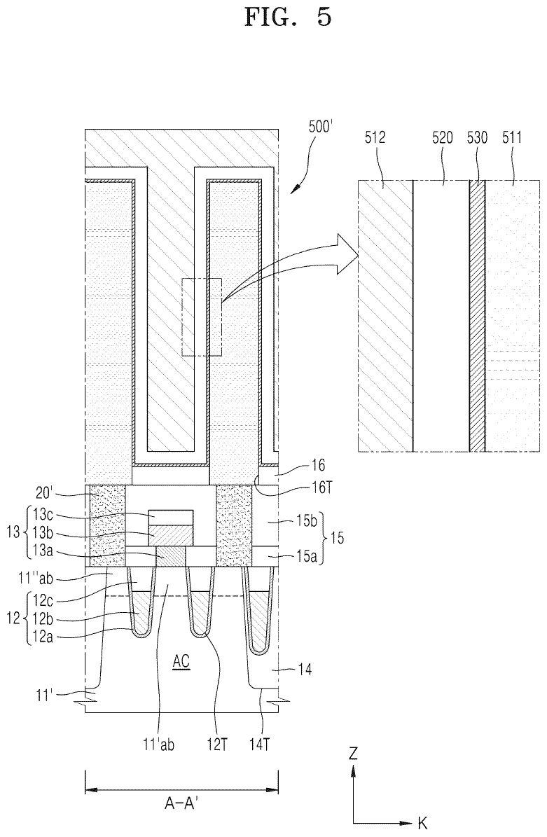

The first electrode 111 may be referred to as a lower electrode and may be arranged on a substrate (not shown). The substrate may be a part of a structure supporting the capacitor 100 or a part of a device connected to the capacitor 100. The substrate may include a pattern of a semiconductor material, a pattern of an insulating material, and/or a pattern of a conductive material. The substrate may include, for example, a substrate 11′, a gate stack 12, an interlayer insulating layer 15, a contact structure 20′, and/or a bit line structure 13, as illustrated in FIGS. 4 and 5 and as described in further detail below.

In at least one embodiment, the substrate includes, for example, a semiconductor material such as silicon (Si), germanium (Ge), silicon germanium (SiGe), silicon carbide (SiC), gallium arsenide (GaAs), indium arsenide (InAs), indium phosphide (InP), and/or the like, and/or an insulating material such as silicon oxide, silicon nitride, silicon oxynitride, and/or the like.

The second electrode 112, which may be referred to as an upper electrode, may be spaced apart from and opposed to the first electrode 111. The first and second electrodes 111 and 112 may each independently include a metal, a metal nitride, a metal oxide, and/or a combination thereof. For example, the first and second electrodes 111 and 112 may each independently include: metals such as ruthenium (Ru), titanium (Ti), tantalum (Ta), niobium (Nb), iridium (Ir), molybdenum (Mo), tungsten (W), platinum (Pt), etc.; conductive metal nitrides such as titanium nitride (TiN), tantalum nitride (TaN), niobium nitride (NbN), molybdenum nitride (MoN), cobalt nitride (CON), tungsten nitride (WN), etc.; and/or conductive metal oxides such as, platinum oxide (PtO), iridium oxide (IrO₂), ruthenium oxide (RuO₂), strontium ruthenium oxide (SrRuO₃), barium strontium ruthenium oxide ((Ba,Sr)RuO₃), calcium ruthenium oxide (CaRuO₃), lanthanum strontium cobalt oxide ((La,Sr)CoO₃), etc.

In at least one embodiment, at least one of the first and/or second electrodes 111 and 112 may include a metal nitride represented by M′M″N. Here, M′ is a metal element, M″ is an element different from M′, and N is nitrogen. The metal nitride may include a M′N metal nitride doped with an element M″.

M′ may be, for example, one or two or more elements selected from: Be, B, Na, Mg. Al, Si, K, Ca, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, and/or U.

M″ may be, for example, one or two or more elements selected from: H, Li, Be, B, N, O, Na, Mg, Al, Si, P, S, K, Ca, Sc, Ti, V, Cr, Mn, Fe, Co, Ni, Cu, Zn, Ga, Ge, As, Se, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, and/or U.

In the capacitor 100, the first electrode includes a first metal ion, and the first metal ion may be a cation of at least one of W, Ta, Ti, Ru, Nb, Sc, Al, Mo, Pd, Pt, Sn, and/or La.

The first and second electrodes 111 and 112 may each independently include a single material layer, or have a structure in which a plurality of material layers are stacked. In a capacitor according to at least one embodiment, the first and second electrodes 111 and 112 may include at least one selected from W. TaN, TiN, RuOₓ, NbN, Sc. Al, Mo, MON, Pd, Pt. Sn, La, and Ru.

For example, according to at least one embodiment, the first and/or the second electrodes 111 and 112 may be a single layer of titanium nitride (TiN) or a single layer of niobium nitride (NbN). Alternatively, the first and/or second electrodes 111 and 112 may have a structure in which a first electrode layer including titanium nitride (TiN) and a second electrode layer including niobium nitride (NbN) are stacked. In at least one embodiment, an interface between the stacked layers may be indistinct and/or indistinguishable such that, when viewed in aggregate the at least one of the first and/or the second electrodes 111 and 112 including the stacked structure includes the composition of MM′N, wherein one of Ti or Nb represents M and the other represents M′.

Referring to FIG. 1, a dielectric layer 120 is provided on an upper surface of the first electrode 111, and an interfacial layer 130 is provided between the first electrode 111 and the dielectric layer.

In the capacitor 100 according to at least one embodiment, the dielectric material may have a perovskite crystal structure. In addition, the dielectric material may include at least one of a three-component or four-component perovskite material.

In the capacitor according to at least one embodiment, the dielectric material may be represented by Formula 1 below:

ABO₃, [Formula 1]
wherein, A may be Ba, Sr, or Ba and Sr; and B may be at least one selected from Ti, V. Cr. Mn, Fe, Co, Zr, Mo, Ru, Hf, and/or Sn.

For example, in at least one embodiment, the three-component perovskite material may include at least one of SrTiO₃ and/or BaTiO₃; and/or the four-component perovskite material may include Sr₁₋ₓBaₓTiO₃, wherein x represents rational number between 0 to 1.

In addition, a single dielectric layer 120 may be formed of the dielectric material, or two or more dielectric sub-layers including different dielectric materials may be formed. For example, the dielectric layer may include at least a first sub-dielectric layer (not shown) and a second sub-dielectric layer (not shown), and the first and second sub-dielectric layers may include different dielectric materials. The first and second sub-dielectric layers may each independently have a single-layer structure including a single material layer, or a multi-layer structure in which a plurality of material layers are stacked.

Meanwhile, so far, cases in which the capacitor 100 has a metal-insulator-metal (MIM) structure, in which both the first and second electrodes 111 and 112 include a conductive material, have been described. However, the example embodiments are not limited thereto, and the capacitor 100 may have a metal-insulator-semiconductor (MIS) structure, in which one of the first and second electrodes includes a conductive material and the other one includes a semiconductor material.

In order to prepare the capacitor 100 of FIG. 1, an interfacial layer 130 may be formed on the first electrode 111, a dielectric layer 120 may be formed on the interfacial layer 130, and a second electrode 112 may be formed on the dielectric layer 120.

For example, the first electrode 111 may be formed on the substrate SU by a deposition process, the interfacial layer 130 may be formed on the first electrode 111 by a deposition process, and the dielectric layer 120 may be formed on the interfacial layer 130 by a deposition process, and the second electrode 112 may be formed on the dielectric layer 120 by a deposition process.

The deposition process used for deposition of each layer may include a chemical vapor deposition (CVD) process, a physical vapor deposition (PVD) process, and/or an atomic layer deposition (ALD) process.

In addition, a high-temperature annealing process may be performed so that the dielectric layer 120 may have a perovskite crystal structure. For example, the annealing process may be performed at a temperature of 400° C. or higher. For example, the annealing process may be performed at a temperature of 500° C. or higher.

In a semiconductor device according to at least one embodiment, an interfacial layer 130 is provided between the first electrode 111 and the dielectric layer 120. The interfacial layer 130 may include a compound represented by MₓO_{y}N₂. Here, M may be one or more selected from Ti, Nb, Ta, V, Ru, Mo, and W. Also, in MₓO_{y}N_{z}, a ratio of z to a sum of y and z may be 0.1 or less, and/or 0 or more. For example, in MₓO_{y}N_{z}, 0≤ z:(y+z)≤ 0.1.

In the semiconductor device according to at least one embodiment, x in MₓO_{y}N₂ may be a rational number from 1 to 3. In addition, in MₓO_{y}N₂, a sum of y and z may be a rational number from 1 to 5. In at least one embodiment, the sum of y and z may be any rational number from 1.5 to 4.5.

In the semiconductor device according to at least one embodiment, a thickness of the interfacial layer 130 may be about 0.1 Å or more and about 20 Å or less. For example, the thickness of the interfacial layer 130 may be about 7 Å to about 12 Å. In at least some embodiments, when the above numerical range is satisfied, capacitance of the capacitor including the interfacial layer 130 is further improved.

A total thickness of the dielectric layer 120 and the interfacial layer 130 may be about 250 Å or less. In addition, a total thickness of the capacitor 100 may be about 300 Å or less. Thus, a highly integrated and high-capacity semiconductor device may be implemented.

In a capacitor according to at least one embodiment, a value of the diffusion energy barrier may be calculated as follows. The diffusion energy barrier values are calculated based on the density functional theory (DFT) using the Vienna ab initio simulation package (VASP). In a perovskite material such as SrTiO₃, cations of the interfacial layer 130 may substitute B-sites where Ti ions are located, and diffusion of these cations occurs when the cations move to adjacent B-sites, when the B sites are empty. When cations move to adjacent B-sites, structural energy increases due to lattice deformation, and a maximum value of the energy increase is the diffusion energy barrier value. The value of an increase of maximum energy according to a movement path is calculated by using the nudged elastic band (NEB) method. The supercell used in the calculation had a size of 3×3×3 unit cells, and generalized gradient approximation (GGA) pseudopotential is used.

In the capacitor according to at least one embodiment, the diffusion energy barrier value of M measured as described above may be about 5.9 eV or more. Specifically, as elements having a diffusion energy barrier value of 5.9 eV or more, Ti, Nb, Ta, V, Ru, Mo, and W are considered.

As described above, the diffusion energy barrier value of M included in the interfacial layer may be equal to or greater than the diffusion energy barrier value of the first metal ion included in the first electrode. As a result, by including the interfacial layer, diffusion of metal ions included in the first electrode may be suppressed in the preparation process of the capacitor according to at least one embodiment. For example, even when a heating process (such as an annealing process) is performed, diffusion of metal ions included in the first electrode may be suppressed. As a result, formation of a low-k dielectric layer due to diffusion of metal ions and side reactions may be suppressed, and high dielectric properties of the dielectric layer may be maintained even after the heating process is performed.

Additionally, the diffusion energy barrier value of M included in the interfacial layer may be equal to or greater than the diffusion energy barrier value of B in Formula 1. As a result, the interfacial layer may suppress diffusion of B included in the dielectric layer, and formation of a low-k dielectric layer due to diffusion of B and side reactions may also be suppressed. As a result, high dielectric properties of the dielectric layer may be maintained even after the heating process is performed.

As a result, the capacitor according to the example embodiments may provide more improved capacitance compared to a capacitor not including an interfacial layer.

In at least some embodiments, when a nitride is used as the first electrode, nitrogen gas may be generated from the first electrode during an annealing process of the dielectric layer, and deformation of the dielectric layer may be caused by the generation of the nitrogen gas. By including the interfacial layer 130, generation of nitrogen gas from the nitride included in the first electrode may be suppressed, and deformation of the dielectric layer due to the generation of nitrogen gas may be suppressed. As a result, compared to a capacitor not including the interfacial layer, the capacitor according to at least one embodiment may include a dielectric layer having a smaller surface roughness. Furthermore, by including a dielectric layer having the smaller surface roughness, the capacitor according to the embodiment may provide more uniform electrical characteristics.

According to another aspect, a semiconductor device may be provided. The semiconductor device may have a form in which a field-effect transistor and a capacitor are electrically connected, and the capacitor may be the same as and/or substantially similar to aforementioned capacitor 100. The semiconductor device may have memory characteristics, and may be, for example, DRAM. However, this is merely illustrative.

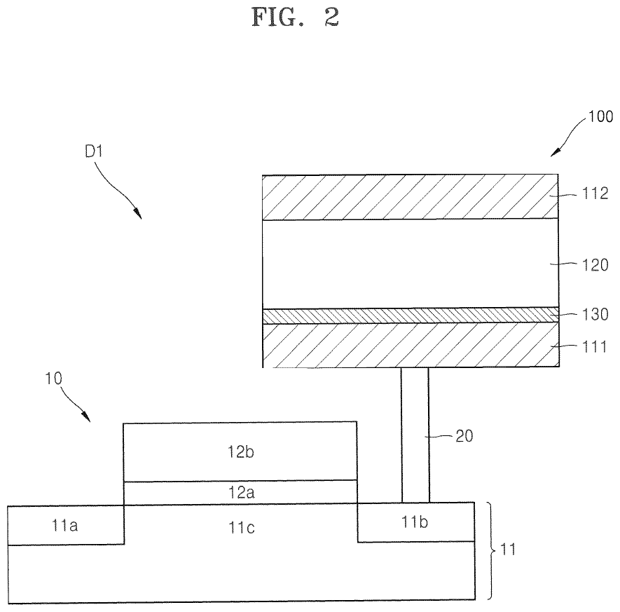

FIG. 2 illustrates a semiconductor device D1 according to at least one embodiment.

Referring to FIG. 2, the semiconductor device D1 may include a field-effect transistor 10 and a capacitor 100 electrically connected to each other by a contact 20. The field-effect transistor 10 may include a substrate 11 including a channel 11c and a gate electrode 12b arranged to face a channel 11c. A dielectric layer 12a may be provided between the substrate 11 and the gate electrode 12b.

The substrate 11 may include a semiconductor material. For example, the substrate 11 may include an elemental and/or a compound semiconductor material such as silicon (Si), germanium (Ge), silicon germanium (SiGe), silicon carbide (SiC), gallium arsenide (GaAs), indium arsenide (InAs), indium phosphide (InP), and/or the like, and/or may be modified and used in various forms, such as silicon on insulator (SOI).

The substrate 11 may include a source 11a, a drain 11b, and a channel 11c electrically connected to the source 11a and the drain 11b. The source 11a may be electrically connected to or in contact with one side of the channel 11c, and the drain 11b may be electrically connected to or in contact with the other side of the channel 11c. For example, the channel 11c may be defined as a substrate region between the source 11a and the drain 11b in the substrate 11.

In at least one embodiment, the source 11a, the drain 11b, and/or the channel 11c may be independently formed by injecting impurities into different regions of the substrate 11, and in this case, the source 11a, the channel 11c, and the drain 11b may include a substrate material as a base material. For example, channel 11c may be doped with a different dopant type and/or dopant quantity compared to the source 11a and/or the drain 11b.

In at least one embodiment, the source 11a and the drain 11b may be formed of a conductive material. The source 11a and the drain 11b may include, for example, a metal, a metal compound, or a conductive polymer.

In at least one embodiment, the channel 11c may be implemented as a material layer (thin film) separate from the substrate 11 (not shown). In this case, for example, the channel 11c may not only include a semiconductor material such as Si, Ge, SiGe, groups III to V, etc., but may also include an oxide semiconductor, a nitride semiconductor, an oxynitride semiconductor, a two-dimensional (2D) material, quantum dots, organic semiconductors, and/or the like. For example, the oxide semiconductor may include InGaZnO, etc., the two-dimensional material may include transition metal dichalcogenide (TMD) or graphene, and the quantum dots may include colloidal quantum dots (QDs), and a nanocrystal structure.

The gate electrode 12b may be disposed on the substrate 11 to be spaced apart from the substrate 11 and to face the channel 11c. The gate electrode 12b may have conductivity of, for example, 1 Mohm/square or less. The gate electrode 12b may include a metal, a metal nitride, a metal carbide, and/or polysilicon. For example, the metal may include at least one of aluminum (Al), tungsten (W), molybdenum (Mo), titanium (Ti), and/or tantalum (Ta), and the metal nitride may be comprised in a film. The film comprising the metal nitride may be referred to as a metal nitride film. The metal nitride film may include a titanium nitride film (TiN film), and/or a tantalum nitride film (TaN film). The metal carbide may be a metal carbide doped with (or containing) aluminum and/or silicon, and may include, e.g., at least one TiAlC, TaAlC, TiSiC, or TaSiC.

The gate electrode 12b may have a structure in which a plurality of materials are stacked, for example, may have a stacked structure of metal nitride layer/metal layer such as TiN/Al, or a stacked structure of metal nitride layer/metal carbide layer/metal layer of TIN/TiAlC/W. The gate electrode 12b may include a titanium nitride (TiN) film, or molybdenum (Mo), and the above example may be used in various modified forms.

A gate insulating layer 12a may be further provided between the substrate 11 and the gate electrode 12b. The gate insulating layer 12a may include a paraelectric material or a high-k dielectric material. The gate insulating layer 12a may include a material with a dielectric constant of approximately 20 to 70. For example, the gate insulating layer 12a may include silicon oxide, silicon nitride, aluminum oxide, hafnium oxide, zirconium oxide, or the like, or may include a 2D insulator such as h-BN (hexagonal boron nitride).

For example, in at least one embodiment, the gate insulating layer 12a may include at least one of silicon oxide (SiO₂), silicon nitride (SiNₓ), hafnium oxide (HfO₂), hafnium silicon oxide (HfSiO₄), lanthanum oxide (La₂O₃), and lanthanum aluminum oxide (LaAlO₃), zirconium oxide (ZrO₂), hafnium zirconium oxide (HfZrO₂), zirconium silicon oxide (ZrSiO₄), tantalum oxide (Ta₂O₅), titanium oxide (TiO₂), strontium titanium oxide (SrTiO₃), yttrium oxide (Y₂O₃), aluminum oxide (Al₂O₃), red scandium tantalum oxide (PbSc_{0.5}Ta_{0.5}O₃), red zinc niobate (PbZnNbO₃), and/or the like. In addition, the gate insulating layer 12a may include: a metal nitride oxide such as aluminum oxynitride (AlON), zirconium oxynitride (ZrON), hafnium oxynitride (HfON), lanthanum oxynitride (LaON), yttrium oxynitride (YON), and/or the like; silicates such as ZrSiON, HfSiON, YSiON, LaSiON, etc.; and/or aluminates such as ZrAlON, HfAlON, etc. However, this is merely illustrative. The gate insulating layer 12a electrically isolates the gate electrode 12b from the channel 11c and constitutes a gate stack together with the gate electrode 12b.

In FIG. 2, a case in which the capacitor 100 has a structure of the capacitor 100 shown in FIG. 1. Since the capacitor 100 has been described above, a detailed description thereof will be omitted.

In at least one embodiment, the field-effect transistor 10 and the capacitor 100 may be electrically connected by a contact 20. For example, one of the first and second electrodes 111 and 112 of the capacitor 100, and one of the source or the drain 11a and 11b of the transistor 10 may be electrically connected by the contact 20. The contact 20 may include any suitable conductive material, such as tungsten, copper, aluminum, polysilicon, and/or the like. In at least one embodiment, the contact 20 may have a structure in which a lower contact pattern (not shown), a metal silicide layer (not shown), and an upper contact pattern (not shown) are sequentially stacked on the drain 11b. Arrangement of the capacitor 100 and the field-effect transistor 10 may be variously modified. For example, the capacitor 100 may be disposed on the substrate 11, or may be buried in the substrate 11. However, the example embodiments are not limited thereto, and, in at least one embodiment, the one of the first and second electrodes 111 and 112 of the capacitor 100 and the one of the source or the drain 11a and 11b of the transistor 10 may directly contact each other.

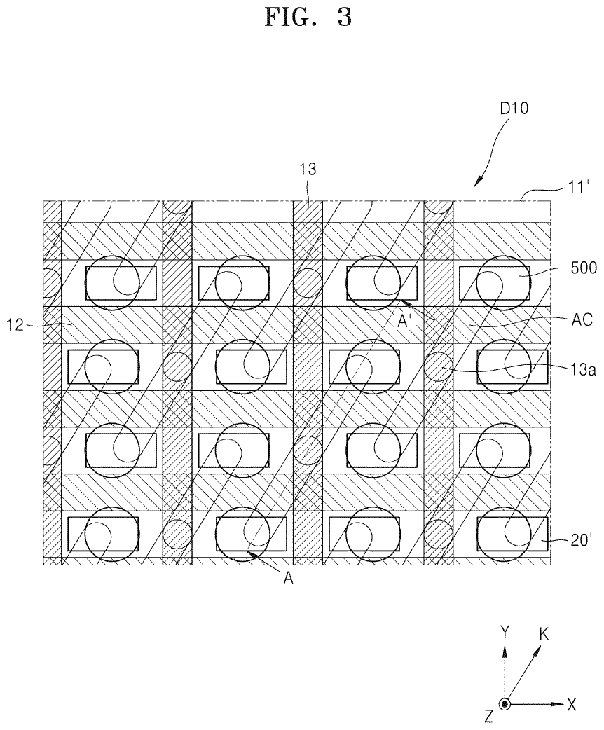

FIG. 3 illustrates a semiconductor device D10 according to at least one embodiment. The semiconductor device D10 shown in FIG. 3 has a structure in which a plurality of capacitors 500 and a plurality of field-effect transistors are repeatedly arranged.

Referring to FIG. 3, the semiconductor device D10 includes a substrate 11′ including a source, a drain, and a channel, a field-effect transistor including a gate stack 12, and a contact structure 20′ disposed on the substrate 11′ so as not to overlap with the gate stack 12, and a capacitor 500 disposed on the contact structure 20′, and a bit line structure 13 electrically connecting a plurality of field-effect transistors may be further included.

FIG. 3 illustrates a semiconductor device D10 in which both the contact structure 20′ and the capacitor 500 are repeatedly arranged along the X and Y directions in an orthogonal shape, but is not limited thereto. For example, the contact structure 20′ may be arranged along the X and Y directions, and the capacitor 500 may be arranged in a hexagonal shape such as a honeycomb structure.

FIG. 4 is a cross-sectional view of the semiconductor device D10 of FIG. 3 taken along the line A-A′.

Referring to FIG. 4, the substrate 11′ may have a shallow trench isolation (STI) structure including a device isolation layer 14. The device isolation layer 14 may be a single layer made of one type of insulating film or a multi-layer made of a combination of insulating films of two or more types. The device isolation layer 14 may include a device isolation trench 14T in the substrate 11′, and the device isolation trench 14T may be filled with an insulating material. The insulation material may include, for example, at least one of fluoride silicate glass (FSG), undoped silicate glass (USG), boro-phospho-silicate glass (BPSG), phospho-silicate glass (PSG), flowable oxide (FOX), and plasma enhanced tetra-ethyl-ortho-silicate (PE-TEOS), and/or tonen silazene (TOSZ), but is not limited thereto.

The substrate 11′ may further include an active region AC defined by the device isolation layer 14, and a gate line trench 12T arranged to be parallel to an upper surface of the substrate 11′ and to extend in an X direction. The active region AC may have a relatively long island shape having short and long axes. As illustrated in FIG. 3, the long axis of the active region AC may be arranged along a K direction parallel to the top surface of the substrate 11′. The gate line trench 12T may be arranged to cross the active region AC at a predetermined depth from the upper surface of the substrate 11′, or arranged within the active region AC. The gate line trench 12T may also be arranged inside the device isolation trench 14T, and the gate line trench 12T inside the device isolation trench 14T may have a bottom surface lower than that of the gate line trench 12T in the active region AC.

A first source/drain 11′ab and a second source/drain 11″ab may be disposed on an upper portion of the active region AC positioned on both sides of the gate line trench 12T. The first source/drain 11′ab and the second source/drain 11″ab may be, for example, the same as (or substantially similar) to the source 11a and the drain 11b in the above description.

A gate stack 12 may be arranged inside the gate line trench 12T. For example, the gate insulating layer 12a, the gate electrode 12b, and the gate capping layer 12c may be sequentially arranged inside the gate line trench 12T. For the gate insulating layer 12a and the gate electrode 12b the above description may be referred to. The gate capping layer 12c includes an insulator, and may include silicon oxide, silicon oxynitride, silicon nitride, and/or the like. A gate capping layer 12c may be disposed on the gate electrode 12b to fill the remaining portion of the gate line trench 12T.

The bit line structure 13 may be disposed on the first source/drain 11′ab. The bit line structure 13 may be arranged to be parallel to the top surface of the substrate 11′ and extend along the Y direction. The bit line structure 13 may be electrically connected to the first source/drain 11′ab, and include a bit line contact 13a, a bit line 13b, and a bit line capping layer 13c, which are sequentially stacked on the substrate 11′. For example, the bit line contact 13a may include a conductive material such as polysilicon, the bit line 13b may include a metal material, and the bit line capping layer 13c may include an insulating material such as silicon nitride and/or silicon oxynitride. In FIG. 4, a case in which the bit line contact 13a has a bottom surface at the same level as the top surface of the substrate 11′ is shown as an example, but the bit line contact 13a may extend from the top surface of the substrate 11′ to the inside of a recess (not shown) formed to a predetermined (or otherwise determined) depth so that the bottom surface of the bit line contact 13a is lower than the top surface of the substrate 11′.

The bit line structure 13 may further include a bit line interlayer (not shown) between the bit line contact 13a and the bit line 13b. The bit line interlayer may include a metal silicide, such as tungsten silicide, and/or a metal nitride, such as tungsten nitride. Also, a bit line spacer (not shown) may be further formed on a sidewall of the bit line structure 13. The bit line spacer may have a single-layer structure or a multi-layer structure, and may include an insulating material such as silicon oxide, silicon oxynitride, or silicon nitride. Also, the bit line spacer may further include an air space (not shown).

The contact structure 20′ may be disposed on the second source/drain 11″ab. The contact structure 20′ and the bit line structure 13 may be disposed on different sources/drains of the substrate 11′. In at least one embodiment, the contact structure 20′ may be the same (or substantially similar to) the contact 20 described above. For example, contact structure 20′ may have a structure in which a lower contact pattern (not shown), a metal silicide layer (not shown), and an upper contact pattern (not shown) are sequentially stacked on the second source/drain 11″ab. In addition, the contact structure 20′ may further include a barrier layer (not shown) surrounding side surfaces and/or a bottom surface of the upper contact pattern. For example, the lower contact pattern may include polysilicon, the upper contact pattern may include a metal material, and the barrier layer may include a conductive metal nitride.

The capacitor 500 may be electrically connected to the contact structure 20′ and disposed on the substrate 11′. Here, the capacitor 500 may be the same as (or substantially similar to) the capacitor 100 according to the above-described embodiments. In FIG. 4, a case in which the capacitor 500 has a structure of the capacitor 100 shown in FIG. 1 is illustratively shown.

The capacitor 500 may include a first electrode 511 electrically connected to the contact structure 20′, a second electrode 512 provided to be spaced apart from the first electrode 511, a dielectric layer 520 provided between the first and second electrodes 511 and 512, and an interfacial layer 530 provided between the first electrode 511 and the dielectric layer 520.

An interlayer insulating layer 15 may be further arranged between the capacitor 500 and the substrate 11′. The interlayer insulating layer 15 may be arranged in a space between the capacitor 500 and the substrate 11′ where no other structures are disposed. Specifically, the interlayer insulating layer 15 may be arranged to cover and/or protect wirings and/or electrode structures, such as the bit line structure 13, the contact structure 20′, and the gate stack 12 on the substrate 11′. For example, the interlayer insulating layer 15 may surround a wall of the contact structure 20′. The interlayer insulating layer 15 may include a first interlayer insulating layer 15a surrounding the bit line contact 13a, and a second interlayer covering the side and/or top surfaces of the bit line 13b and the bit line capping layer 13c.

The first electrode 511 of the capacitor 500 may be arranged on the interlayer insulating layer 15, for example, on the second interlayer insulating layer 15b. In addition, when a plurality of capacitors 500 are arranged, bottom surfaces of the plurality of first electrodes 511 may be separated by a etch stop layer 16. For example, the etch stop layer 16 may include an opening 16T, and a bottom surface of the first electrode 511 of the capacitor 500 may be arranged in the opening 16T.

As shown in FIG. 4, the first electrode 511 may have a cylindrical shape or a cup shape with a closed bottom. Meanwhile, as another example, as in the capacitor 500′ shown in FIG. 5, the first electrode 511 may have a pillar shape such as a cylinder, a quadrangular column, or a polygonal column extending along the vertical direction (Z direction). The capacitor 500 may further include a supporter (not shown) preventing (protecting) the first electrode 511 from tilting or falling, and the supporter may be arranged on a sidewall of the first electrode 511.

The semiconductor device D10 described above may be manufactured by referring to a common method known in the art. For example, the semiconductor device D10 may be prepared by a method including i) to xvi) below:
i) forming a device isolation trench 14T on a substrate 11′, and forming a device isolation layer 14 in the device isolation trench 14T. (defining an active region AC of the substrate 102 by the device isolation layer 14 and/or the device isolation trench 14T);
ii) filling the inside of the device isolation trench 14T with an insulating material;
iii) forming a first source/drain 11′ab and a second source/drain 11″ab in an upper region of the active region AC by injecting impurity ions into the substrate 11′;
iv) forming a gate line trench 12T in the substrate 11′;
v) forming a gate insulating layer 12a, a gate electrode 12b, and a gate capping layer 12c inside the gate line trench 12T;
vi) forming a first interlayer insulating layer 15a on the substrate 11′ and forming an opening (not shown) exposing an upper surface of the first source/drain 11′ab;
vii) forming a bit line structure 13 electrically connected to the first source/drain 11′ab on the opening of vi);
viii) forming a second interlayer insulating layer 15b covering the top and side surfaces of the bit line structure 13;
ix) forming an opening (not shown) in the first and second interlayer insulating layers 15a and 15b to expose an upper surface of the second source/drain 11″ab;
x) forming a contact structure 20′ electrically connected to the second source/drain 11″ab on the opening of ix);
xi) forming an etch stop layer 16 and a mold layer (not shown) on the second interlayer insulating film 15b and the contact structure 20′;
xii) forming an opening (not shown) in the etch stop layer 16 and the mold layer (not shown) to expose an upper surface of the contact structure 20′;
xiii) forming a first electrode 511 to cover the inner wall of the opening of xii) (to cover the bottom and side surfaces);
xiv) removing the mold layer (not shown);
xv) forming an interfacial layer 530 and a dielectric layer 520 on the first electrode 511; and
xvi) Forming a second electrode 512 on the dielectric layer 520.

The type and/or order of each process described above is not limited thereto, and may be appropriately adjusted, and some processes may be omitted or added. In addition, for forming components in each process, a deposition process, a patterning process, an etching process, and/or the like known in the art may be used. For example, an etch-back process may be applied when forming an electrode. In v), the gate electrode 12b may be formed by forming a conductive layer on the gate insulating layer 12a and then removing an upper portion of the conductive layer to a predetermined height through an etch-back process. In addition, in xiii), the first electrode 511 may be formed to cover both an upper surface of the mold layer and bottom and side surfaces of the opening, and then, by removing a part of the electrode on the upper surface of the mold layer by an etch-back process, a structure having a plurality of first electrodes 511 may be prepared. As another example, a planarization process may be applied. For example, in v), the gate capping layer 12c may be formed by filling the remaining portion of the gate line trench 12T with an insulating material and then planarizing the insulating material until the upper surface of the substrate 11′ is exposed.

According to another aspect, the above-described capacitor 100 and the semiconductor devices D1 and D10 may be applied to various electronic apparatuses. For example, the above-described capacitors 100 and 500 and/or the semiconductor devices D1 and D10 may be applied as logic devices or memory devices in various electronic apparatuses. For example, the capacitors 100 and 500 and/or the semiconductor devices D1 and D10 may be used to perform arithmetic operations, execute programs, and retain temporary data, in electronic apparatuses such as mobile devices, computers, laptops, sensors, network devices, and neuromorphic devices. The capacitors and semiconductor devices according to some embodiments may be useful for electronic apparatuses in which a large amount of data is transmitted, and data is continuously transmitted.

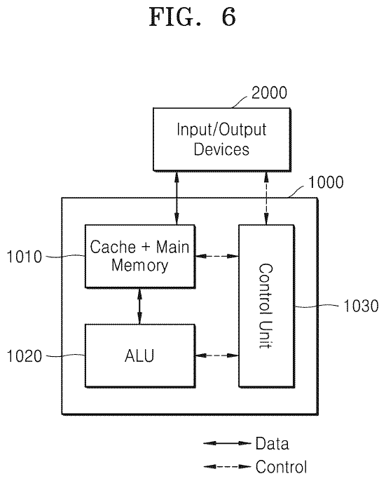

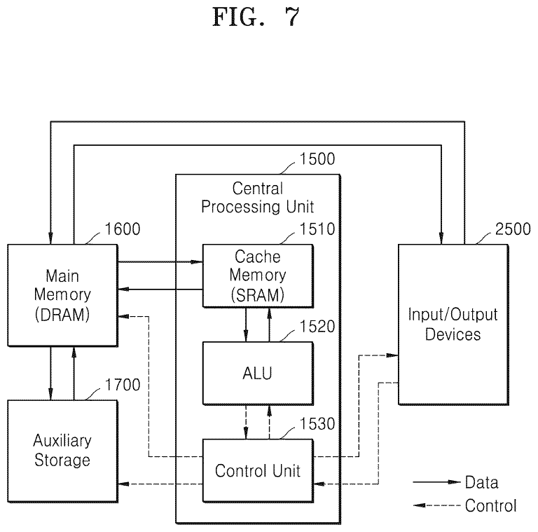

FIGS. 6 and 7 are conceptual diagrams schematically illustrating device architectures applicable to electronic apparatuses according to some embodiments.

Referring to FIG. 6, a device architecture 1000 may include a memory unit 1010, an arithmetic logic unit (ALU) 1020, and a control unit 1030. The memory unit 1010, ALU 1020 and the control unit 1030 may be electrically connected. For example, the electronic device architecture 1000 may be implemented as a single chip including a memory unit 1010, ALU 1020 and a control unit 1030. Specifically, the memory unit 1010, ALU 1020, and the control unit 1030 may be connected to each other through a metal line on-chip to communicate directly. The memory unit 1010, ALU 1020, and the control unit 1030 may be monolithically integrated on one substrate to form one chip. An input/output device 2000 may be connected to the device architecture 1000. Also, the memory unit 1010 may include both a main memory and a cache memory. This device architecture 1000 may be an on-chip memory processing unit. The memory unit 1010, ALU 1020, and/or the control unit 1030 may each independently include the aforementioned capacitor.

Referring to FIG. 7, a cache memory 1510, ALU 1520, and a control unit 1530 may configure a Central Processing Unit (CPU) 1500, and the cache memory 1510 may consist of a static random access memory (SRAM). Apart from CPU 1500, a main memory 1600, an auxiliary storage 1700, and at least one input/output devices 2500 may be provided. The CPU 1500 and/or the main memory 1600 may be connected to at least one input/output device 2500. The input/output device (and/or devices) 2500 may include, for example, an input device (such as a microphone, touch pad, electronic mouse, keyboard, keypad, camera, etc.) and/or an output device (such as a speaker, display, haptic system, etc.). The at least one input/output device 2500 may include, for example, an input device (such as a microphone, touch pad, electronic mouse, keyboard, keypad, camera, etc.) and/or an output device (such as a speaker, display, haptic system, etc.). According to at least some example embodiments, the at least one input/output device 2500 may be provided individually and/or in combination (e.g., a touch screen display).

At least one of the CPU 1500, the main memory 1600, the auxiliary storage 1700, and/or an input/output device 2500 may include the aforementioned capacitor. For example, the main memory 1600 may be dynamic random access memory (DRAM) and may include the aforementioned capacitor. In some cases, the device architecture may be implemented in a form in which computing unit devices and memory unit devices are adjacent to each other in one chip without distinguishing sub-units.

### Examples and Evaluation Examples

Hereinafter, the present disclosure will be described in more detail through examples and comparative examples. However, these are only some examples, and various modifications are possible therefrom for those skilled in the art.

### Example 1

As a first electrode, TiN having a thickness of about 100 Å was prepared. As an interfacial layer on the first electrode, TiO_{1.85}N_{0.15} having a thickness of about 7 Å was prepared. SrTiO₃ having a thickness of about 50 Å was prepared as a dielectric layer on the interfacial layer. The dielectric layer was annealed at a temperature of about 500° C. A capacitor was manufactured by preparing RuO₂ having a thickness of about 50 Å as a second electrode on the dielectric layer.

### Examples 2 to 4

The examples were prepared in the same way as in Example 1, but thicknesses of the interfacial layer were changed as shown in Table 1 below.

### Comparative Example 1

Comparative Example 1 was prepared in the same manner as Example 1, but the interfacial layer was excluded.

### Evaluation Example

Capacitances of the capacitors of Examples 1 to 4 and Comparative Example 1 were measured. Capacitance was measured by applying a voltage between −1 V and 1 V at intervals of 0.05 V in Keysight E4980A Precision LCR Meter equipment, and capacitance values at 0 V were taken.

Also, for dielectric layers of Example 2 and Comparative Example 1, surface roughness was measured. Surface roughness was calculated by scanning a 2 μm×2 μm image on a Bruker Dimension icon machine and obtaining root-mean-square roughness (Rq) within the image.

The measurement results of capacitance and surface roughness are shown in Table 1 below.

TABLE 1

| | Thickness of | Surface roughness | |
|---|---|---|---|
| Measurement | interfacial | of dielectric | Capacitance |
| target | layer (Å) | layer (Rq, Å) | (10⁻¹⁰ F) |
| Example 1 | 7 | — | 6.3 |
| Example 2 | 9 | 15.0 | 7.3 |
| Example 3 | 11 | — | 7.1 |
| Example 4 | 12 | — | 6.0 |
| Comparative | — | 25.7 | 5.0 |
| Example 1 | | | |

Referring to Table 1, all of the capacitors according to Examples 1 to 4 have capacitance improved by 1.0×10⁻¹⁰ F or more compared to the capacitor according to Comparative Example 1.

In addition, the dielectric layer included in the capacitors according to the examples has less surface roughness than the dielectric layer included in the capacitor according to Comparative Example 1. As a result, the capacitors according to the examples is expected to provide uniform electrical characteristics compared to the capacitor according to Comparative Example 1.

By providing the interfacial layer as described above, formation of a low-k dielectric layer may be suppressed, and capacitance may be increased in preparation processes of the capacitor (semiconductor device) according to at least one embodiment.

In addition, by providing the interfacial layer as described above, surface roughness of a dielectric layer may be improved.

In addition, the capacitor may be applied to semiconductor devices such as DRAMs and electronic apparatuses such as mobile devices, computers, laptops, sensors, network devices, and neuromorphic devices.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A capacitor comprising:
a first electrode including a first metal ion;
a second electrode spaced apart from the first electrode;
a dielectric layer between the first electrode and the second electrode, the dielectric layer comprising a dielectric material with a perovskite crystal structure; and
an interfacial layer between the first electrode and the dielectric layer, the interfacial layer including a compound represented by MₓO_{y}N_{z},
wherein a diffusion energy barrier value of M is equal to or greater than a diffusion energy barrier value of the first metal ion.

2. The capacitor of claim 1, wherein the first metal ion is a cation of at least one of W, Ta, Ti, Ru, Nb, Sc, Al, Mo, Pd, Pt, Sn, or La.

3. The capacitor of claim 1, wherein at least one of the first and second electrodes comprises at least one of W, TaN, TiN, RuOₓ, NbN, Sc, Al, Mo, MON, Pd, Pt, Sn, La, or Ru.

4. The capacitor of claim 1, wherein one of the first and second electrodes comprises a semiconductor material.

5. The capacitor of claim 1, wherein the dielectric material comprises a three-component or four-component perovskite material.

6. The capacitor of claim 1, wherein the dielectric material is represented by ABO₃,
wherein A is one of Ba, Sr, or Ba and Sr; and
B is at least one of Ti, V, Cr, Mn, Fe, Co, Zr, Mo, Ru, Hf, or Sn.

7. The capacitor of claim 6, wherein the diffusion energy barrier value of M is equal to or greater than a diffusion energy barrier value of the B in the ABO₃.

8. The capacitor of claim 1, wherein the dielectric layer is at least one of a single-layer structure or a multi-layer structure in which different materials are stacked.

9. The capacitor of claim 1, wherein the diffusion energy barrier value of M is 5.9 eV or more.

10. The capacitor of claim 1, wherein M is at least one of Ti, Nb, Ta, V, Ru, Mo, or W.

11. The capacitor of claim 1, wherein in the compound represent by MₓO_{y}N_{z}, a ratio of z to a sum of y and z is 0.1 or less.

12. The capacitor of claim 1, wherein a thickness of the interfacial layer is 20 Å or less.

13. The capacitor of claim 1, wherein a thickness of the interfacial layer is 7 Å to 12 Å.

14. The capacitor of claim 1, wherein a total thickness of the capacitor is 300 Å or less.

15. A semiconductor device comprising:
a field-effect transistor; and
a capacitor electrically connected to the field-effect transistor,
wherein the capacitor includes
a first electrode including a first metal ion;
a second electrode spaced apart from the first electrode;
a dielectric layer between the first electrode and the second electrode; and
an interfacial layer between the first electrode and the dielectric layer, the interfacial layer including a compound represented by MₓO_{y}N_{z},
wherein a diffusion energy barrier value of M is greater than or equal to a diffusion energy barrier value of the first metal ion.

16. The semiconductor device of claim 15, wherein the field-effect transistor comprises:
a source and a drain,
a channel between the source and the drain,
a gate dielectric layer on the channel, and
a gate electrode on the gate dielectric layer.

17. The semiconductor device of claim 15, wherein the first metal ion is a cation of at least one of W, Ta, Ti, Ru, Nb, Sc, Al, Mo, Pd, Pt, Sn, or La.

18. The semiconductor device of claim 15, wherein the dielectric layer comprises a dielectric material with a perovskite crystal structure.

19. The semiconductor device of claim 15, wherein a thickness of the capacitor is 300 Å or less.

20. An electronic apparatus comprising the semiconductor device of claim 15.
